(19) United States
(12) Patent Application Publication
(10) Pub. No.: US 2024/0313104 A1
(43) Pub. Date: Sep. 19, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masaru FURUKAWA, Himeji Hyogo (JP)

(21) Appl. No.: 18/450,656

(22) Filed: Aug. 16, 2023

(30) Foreign Application Priority Data
Mar. 17, 2023 (JP) 2023-043639

(51) Int. Cl. H01L 29/78; H01L 29/06; H01L 29/10; H01L 29/16

(52) U.S. Cl. CPC H01L 29/7802; H01L 29/063; H01L 29/0696; H01L 29/1095; H01L 29/1608

(57) ABSTRACT

A semiconductor device according to an embodiment includes a silicon carbide layer having a first face and a second face; a first silicon carbide region of a first conductivity type; a second silicon carbide region of a second conductivity type; a third silicon carbide region of the first conductivity type in the silicon carbide layer in this order in a direction from the second face to the first face; and a gate electrode. The first silicon carbide region includes a first region, second regions, and third regions. The second regions and the third regions are provided between the first region and the second silicon carbide region. The second regions and the third regions are alternately provided in a first direction parallel to the first face, and the first conductivity type impurity concentration of the second regions is higher than those of the first region and the third regions.

### CROSS-REFERENCE TO RELATED APPLICATION

This application is based upon and claims the benefit of priority from Japanese Patent Application No. 2023-043639, filed on Mar. 17, 2023, the entire contents of which are incorporated herein by reference.

### FIELD

Embodiments described herein relate generally to a semiconductor device.

### BACKGROUND

Silicon carbide is a material for a semiconductor device. Silicon carbide is a material for semiconductor devices. Compared to silicon, silicon carbide has excellent physical properties: with a band gap about three times greater, a breakdown field strength about ten times greater, and a thermal conductivity about three times greater. By utilizing these characteristics, it is possible to achieve, for example, a metal-oxide-semiconductor field-effect transistor (MOSFET) capable of operating at a high breakdown voltage, a low loss, and a high temperature.

For improving the performance of the MOSFET using silicon carbide, it is desirable to reduce the product (Ron×Qoss) of on-resistance and an output charge amount, which is one of performance indexes. The output charge amount (Qoss) is the amount of charge required for charging a capacitance between the drain and the source of the MOSFET.

### BRIEF DESCRIPTION OF THE DRAWINGS

FIGS. 1A and 1B are schematic sectional views of a semiconductor device according to a first embodiment;

FIG. 2 is a schematic top view of the first embodiment;

FIGS. 3A and 3B are schematic sectional views of the semiconductor device according to the first embodiment;

FIGS. 4A and 4B are schematic sectional views of a semiconductor device according to a first comparative example;

FIG. 5 is an explanatory diagram of functions and effects of the semiconductor device according to the first embodiment;

FIGS. 6A and 6B are schematic sectional views of a semiconductor device according to a second comparative example;

FIG. 7 is an explanatory diagram of functions and effects of the semiconductor device according to the first embodiment;

FIGS. 8A and 8B are schematic views of semiconductor devices according to a first modification and a second modification of the first embodiment;

FIG. 9 is a schematic sectional view of a semiconductor device according to a second embodiment;

FIG. 10 is a schematic sectional view of the semiconductor device according to the second embodiment;

FIG. 11 is a schematic top view of the second embodiment;

FIG. 12 is a schematic sectional view of the semiconductor device according to the second embodiment;

FIG. 13 is a schematic sectional view of the semiconductor device according to the second embodiment;

FIG. 14 is an explanatory diagram of functions and effects of the semiconductor device according to the second embodiment;

FIGS. 15A and 15B are schematic sectional views of a semiconductor device according to a third embodiment;

FIG. 16 is a schematic top view of the third embodiment;

FIGS. 17A and 17B are schematic sectional views of the semiconductor device according to the third embodiment;

FIGS. 18A and 18B are schematic sectional views of a semiconductor device according to a fourth embodiment;

FIG. 19 is a schematic top view of the fourth embodiment; and

FIGS. 20A and 20B are schematic sectional views of the semiconductor device according to the fourth embodiment.

### DETAILED DESCRIPTION

A semiconductor device according to an embodiment includes: a silicon carbide layer having a first face and a second face facing the first face; a first electrode provided on a side of the first face of the silicon carbide layer; a second electrode provided on a side of the second face of the silicon carbide layer; a first silicon carbide region of a first conductivity type provided in the silicon carbide layer; a second silicon carbide region of a second conductivity type provided in the silicon carbide layer and provided between the first silicon carbide region and the first face; a third silicon carbide region of the first conductivity type provided in the silicon carbide layer and provided between the second silicon carbide region and the first face, the third silicon carbide region being in contact with the first electrode; a gate electrode provided on the first face side of the silicon carbide layer and facing the second silicon carbide region; and a gate insulating layer provided between the gate electrode and the second silicon carbide region. The first silicon carbide region includes a first region, a plurality of second regions provided between the first region and the second silicon carbide region and in contact with the second silicon carbide region, and a plurality of third regions provided between the first region and the second silicon carbide region and in contact with the second silicon carbide region. The second regions and the third regions are alternately provided in a first direction parallel to the first face. A first conductivity type impurity concentration in each of the second regions is higher than a first conductivity type impurity concentration in the first region and a first conductivity type impurity concentration in each of the third regions.

Embodiments of the present disclosure will be described below with reference to the drawings. In the following description, the same or similar members or the like are denoted by the same reference numeral, and the description of the member or the like once described may be omitted as appropriate.

Further, in the following description, notations n⁺, n, and n⁻ and p⁺, p, and p-represent relative levels of impurity concentration in each conductivity type. That is, n⁺ indicates a relatively higher concentration of n-type impurities than n, and n⁻ indicates a relatively lower concentration of n-type impurities than n. In addition, p⁺ indicates a relatively higher concentration of p-type impurities than p, and p⁻ indicates a relatively lower concentration of p-type impurities than p. Note that n⁺ type and n⁻ type may be simply referred to as n-type, p⁺ type, and p⁻ type may be simply referred to as p-type. The impurity concentration can be measured by, for example, secondary-ion mass spectrometry (SIMS). The relative level of the impurity concentration can also be determined from the level of the carrier concentration obtained by, for example, scanning capacitance microscopy (SCM). In addition, the depth, thickness, and other distances of the impurity region can be obtained by, for example, SIMS. Also, the depth, thickness, width, spacing, and other distances of the impurity region can be obtained from, for example, a composite image of an SCM image and an atomic force microscope (AFM) image.

### First Embodiment

A semiconductor device according to a first embodiment includes: a silicon carbide layer having a first face and a second face facing the first face; a first electrode provided on a side of the first face of the silicon carbide layer; a second electrode provided on a side of the second face of the silicon carbide layer; a first silicon carbide region of a first conductivity type provided in the silicon carbide layer; a second silicon carbide region of a second conductivity type provided in the silicon carbide layer and provided between the first silicon carbide region and the first face; a third silicon carbide region of the first conductivity type provided in the silicon carbide layer and provided between the second silicon carbide region and the first face, the third silicon carbide region being in contact with the first electrode; a gate electrode provided on the first face side of the silicon carbide layer and facing the second silicon carbide region; and a gate insulating layer provided between the gate electrode and the second silicon carbide region. The first silicon carbide region includes a first region, a plurality of second regions provided between the first region and the second silicon carbide region and in contact with the second silicon carbide region, and a plurality of third regions provided between the first region and the second silicon carbide region and in contact with the second silicon carbide region. The second regions and the third regions are alternately provided in a predetermined direction parallel to the first face. A first conductivity type impurity concentration in each of the second regions is higher than a first conductivity type impurity concentration in the first region and a first conductivity type impurity concentration in each of the third regions.

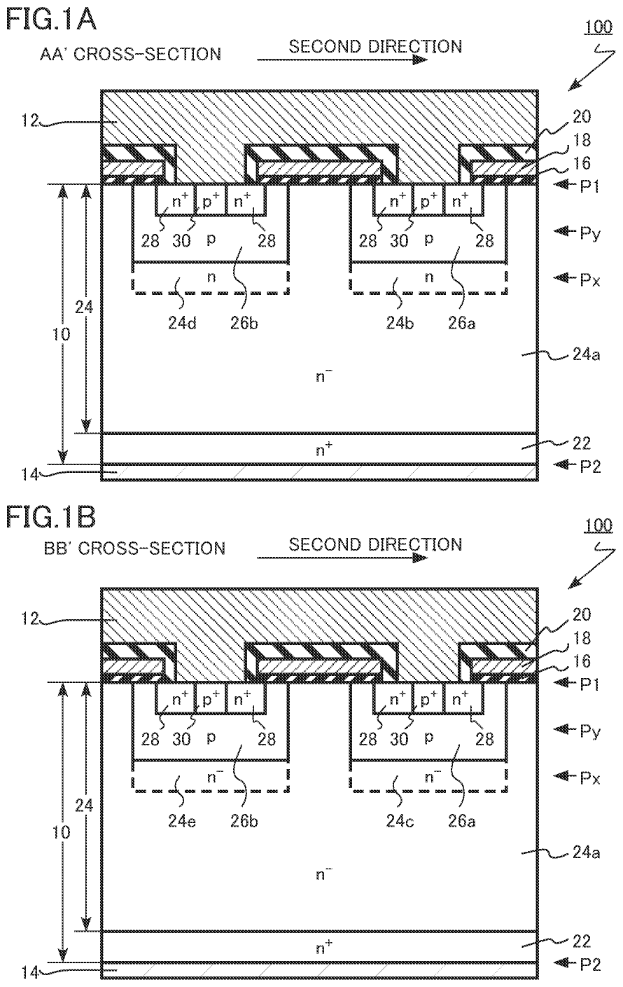

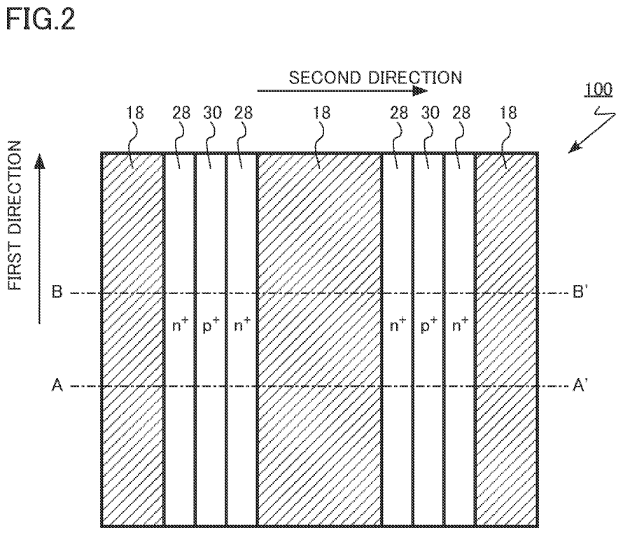

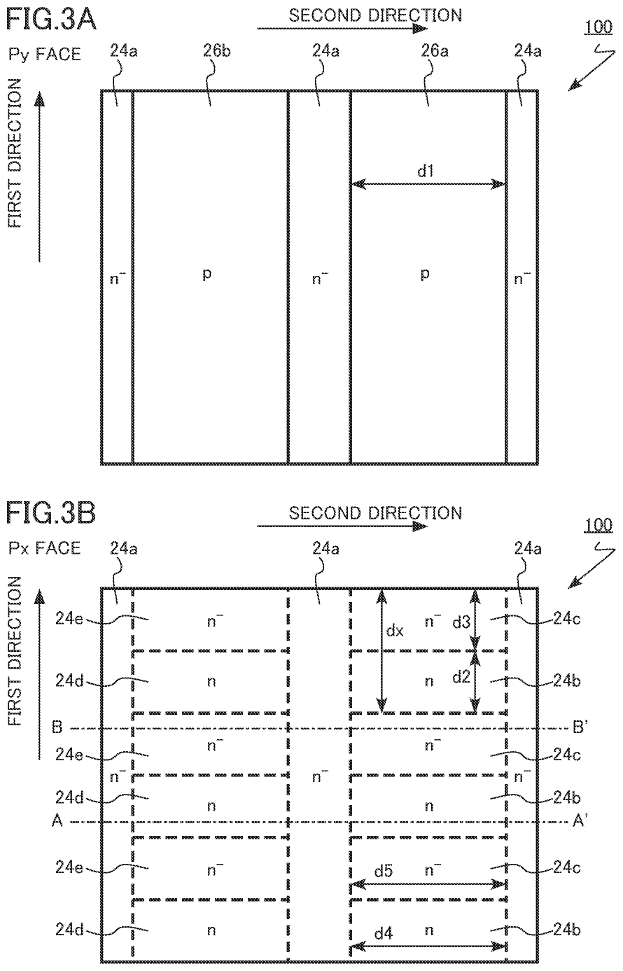

FIGS. 1A and 1B are schematic sectional views of the semiconductor device according to the first embodiment. FIG. 2 is a schematic top view of the first embodiment. FIG. 2 is a view of the pattern of the gate electrode overlaid with the pattern of the silicon carbide region on the front surface of the silicon carbide layer. FIGS. 3A and 3B are schematic sectional views of the semiconductor device according to the first embodiment.

FIG. 1A is a cross-section taken along line AA′ of FIGS. 2 and 3B. FIG. 1B is a cross-section taken along line BB′ of FIGS. 2 and 3B. FIG. 3A is a sectional view taken along face Py of FIGS. 1A and 1B. FIG. 3B is a sectional view taken along face Px of FIGS. 1A and 1B.

The semiconductor device according to the first embodiment is a planar-gate-type vertical MOSFET 100 using silicon carbide. The MOSFET 100 of the first embodiment is, for example, a double implantation MOSFET (DIMOSFET) in which a body region and a source region are formed by ion implantation.

A case where the first conductivity type is n-type and the second conductivity type is p-type will be described below as an example. The MOSFET 100 is a vertical n-channel MOSFET using electrons as carriers.

The MOSFET 100 includes a silicon carbide layer 10, a source electrode 12, a drain electrode 14, a gate insulating layer 16, a gate electrode 18, and an interlayer insulating layer 20. The source electrode 12 is an example of a first electrode. The drain electrode 14 is an example of a second electrode.

In the silicon carbide layer 10, an n⁺ type drain region 22, an n⁻ type drift region 24, a p-type first body region 26a, a p-type second body region 26b, an n⁺ type source region 28, and a p⁺ type body contact region 30 are provided. The drift region 24 is an example of a first silicon carbide region. The first body region 26a is an example of a second silicon carbide region. The second body region 26b is an example of a fourth silicon carbide region. The source region 28 is an example of a third silicon carbide region.

The drift region 24 includes a main region 24a, a first high-concentration region 24b, a first low-concentration region 24c, a second high-concentration region 24d, and a second low-concentration region 24e. The main region 24a is an example of a first region. The first high-concentration region 24b is an example of a second region. The first low-concentration region 24c is an example of a third region. The second high-concentration region 24d is an example of a fourth region. The second low-concentration region 24e is an example of a fifth region.

The silicon carbide layer 10 is provided between the source electrode 12 and the drain electrode 14. The silicon carbide layer 10 is provided between the gate electrode 18 and the drain electrode 14. The silicon carbide layer 10 is single crystal SiC. The silicon carbide layer 10 is, for example, 4H—SiC.

The silicon carbide layer 10 includes a first face (“P1” in FIG. 1) and a second face (“P2” in FIG. 1). In the following, the first face may be referred to as a front surface, and the second face may be referred to as a back surface. Note that the “depth” hereinafter means a depth with the first face as a reference.

The first face P1 is, for example, a face inclined at 0 degrees or more and 8 degrees or less with respect to the (0001) face. The second face P2 is, for example, a face inclined at an angle of 0 degrees or more and 8 degrees or less with respect to the (000-1) face. The (0001) face is called a silicon face. The (000-1) face is called a carbon face.

The n⁺ type drain region 22 is provided on the back surface side of the silicon carbide layer 10. The drain region 22 contains, for example, nitrogen (N) as n-type impurities. The n-type impurity concentration in the drain region 22 is, for example, 1×10¹⁸ cm⁻³ or more and 1×10²¹ cm⁻³ or less.

The n⁻ type drift region 24 is provided between the drain region 22 and the first face P1. The drift region 24 is provided between the source electrode 12 and the drain electrode 14. The drift region 24 is provided between the gate electrode 18 and the drain electrode 14.

The drift region 24 is provided on the drain region 22. The drift region 24 is, for example, a region formed on the drain region 22 using an epitaxial growth method.

The drift region 24 contains, for example, nitrogen (N) as n-type impurities. The n-type impurity concentration in the drift region 24 is lower than the n-type impurity concentration in the drain region 22. The n-type impurity concentration in the drift region 24 is, for example, 4×10¹⁴ cm⁻³ or more and 1×10¹⁸ cm⁻³ or less. The thickness of the drift region 24 is, for example, 5 μm or more and 150 μm or less.

The p-type first body region 26a and second body region 26b are provided between the drift region 24 and the first face P1. The first body region 26a and the second body region 26b are separated from each other.

The first body region 26a and the second body region 26b extend in a first direction parallel to the first face P1. The second body region 26b is provided in a second direction parallel to the first face P1 and orthogonal to the first direction with respect to the first body region 26a.

The first body region 26a and the second body region 26b function as the channel regions of the MOSFET 100.

The first body region 26a and the second body region 26b contain, for example, aluminum (Al) as p-type impurities. The p-type impurity concentration in the first body region 26a and the second body region 26b is, for example, 1×10¹⁷ cm⁻³ or more and 1×10¹⁸ cm⁻³ or less.

The depths of the first body region 26a and the second body region 26b are, for example, 0.3 μm or more and 1.5 μm or less.

The first body region 26a and the second body region 26b are fixed to the electric potential of the source electrode 12.

The n⁺ type source region 28 is provided between the first body region 26a and the first face P1. The n⁺ type source region 28 is provided between the second body region 26b and the first face P1.

The source region 28 contains, for example, phosphorus (P) as n-type impurities. The n-type impurity concentration in the source region 28 is higher than the n-type impurity concentration in the drift region 24.

The n-type impurity concentration in the source region 28 is, for example, 1×10¹⁹ cm⁻³ or more and 1×10²¹ cm⁻³ or less. The depth of the source region 28 is shallower than the depths of the first body region 26a and the second body region 26b, and is, for example, 0.1 μm or more and 0.5 μm or less.

The source region 28 is in contact with the source electrode 12. The junction between the source region 28 and the source electrode 12 is, for example, an ohmic junction.

The source region 28 is fixed to the electric potential of the source electrode 12.

The p⁺ type body contact region 30 is provided between the first body region 26a and the first face P1. The p⁺ type body contact region 30 is provided between the second body region 26b and the first face P1.

The p-type impurity concentration in the body contact region 30 is higher than the p-type impurity concentration in the first body region 26a and the second body region 26b.

The body contact region 30 contains, for example, aluminum (Al) as p-type impurities. The p-type impurity concentration in the body contact region 30 is, for example, 5×10¹⁹ cm⁻³ or more and 1×10²¹ cm⁻³ or less.

The depth of the body contact region 30 is, for example, 0.3 μm or more and 0.6 μm or less.

The body contact region 30 is in contact with the source electrode 12.

The gate electrode 18 is provided on the first face P1 side of the silicon carbide layer 10. As illustrated in FIG. 2, the gate electrode 18 extends in the first direction parallel to the first face P1. A plurality of gate electrodes 18 are disposed in parallel to each other in the second direction parallel to the first face P1 and orthogonal to the first direction. The gate electrode 18 has a stripe pattern on the first face P1.

The gate electrode 18 is a conductive layer. The gate electrode 18 is, for example, polycrystalline silicon containing p-type impurities or n-type impurities.

The gate electrode 18 faces, for example, a portion of the first body region 26a in contact with the first face P1. The gate electrode 18 faces, for example, a portion of the second body region 26b in contact with the first face P1.

The gate insulating layer 16 is provided between the gate electrode 18 and the first body region 26a, and is provided between the gate electrode 18 and the second body region 26b. The gate insulating layer 16 is provided between the gate electrode 18 and the drift region 24.

The gate insulating layer 16 is, for example, silicon oxide. For example, a high-k insulating material (high dielectric constant insulating material) can be applied to the gate insulating layer 16.

The interlayer insulating layer 20 is provided on the gate electrode 18 and the silicon carbide layer 10. The interlayer insulating layer 20 is, for example, silicon oxide.

The source electrode 12 is in contact with the source region 28. The source electrode 12 is in contact with the body contact region 30.

The source electrode 12 contains metal. The metal forming the source electrode 12 is, for example, a stacked structure of titanium (Ti) and aluminum (Al). A portion of the source electrode 12 in contact with the source region is, for example, metal silicide. The metal silicide is, for example, titanium silicide or nickel silicide.

The drain electrode 14 is provided on the back surface of the silicon carbide layer 10. The drain electrode 14 is in contact with the drain region 22.

The drain electrode 14 is, for example, metal or a metal-semiconductor compound. The drain electrode 14 contains, for example, at least one material selected from the group consisting of nickel silicide, titanium (Ti), nickel (Ni), silver (Ag), and gold (Au).

The drift region 24 includes an n-type main region 24a, a plurality of n-type first high-concentration regions 24b, a plurality of n-type first low-concentration regions 24c, a plurality of n-type second high-concentration regions 24d, and a plurality of n-type second low-concentration regions 24e.

The main region 24a contains, for example, nitrogen (N) as n-type impurities. The n-type impurity concentration in the main region 24a is, for example, 4×10¹⁴ cm⁻³ or more and 1×10¹⁷ cm⁻³ or less.

The plurality of first high-concentration regions 24b are provided between the main region 24a and the first body region 26a. The plurality of first high-concentration regions 24b are in contact with the first body region 26a. The plurality of first high-concentration regions 24b is in contact with, for example, the main region 24a.

The plurality of first low-concentration regions 24c are provided between the main region 24a and the first body region 26a. The plurality of first low-concentration regions 24c are in contact with the first body region 26a. The plurality of first low-concentration regions 24c is in contact with, for example, the main region 24a.

As illustrated in FIG. 3A, the first body region 26a extends in the first direction. As illustrated in FIG. 3B, the first high-concentration regions 24b and the first low-concentration regions 24c are alternately provided in the first direction. One first low-concentration region 24c is sandwiched between two first high-concentration regions 24b in the first direction. The first high-concentration region 24b and the first low-concentration region 24c are in contact with each other.

The first high-concentration region 24b contains, for example, nitrogen (N) as n-type impurities. The n-type impurity concentration in the first high-concentration region 24b is higher than the n-type impurity concentration in the main region 24a. The n-type impurity concentration in the first high-concentration region 24b is higher than the n-type impurity concentration in the first low-concentration region 24c.

The n-type impurity concentration in the first high-concentration region 24b is, for example, 5×10¹⁶ cm⁻³ or more and 1×10¹⁸ cm⁻³ or less.

The first low-concentration region 24c contains, for example, nitrogen (N) as n-type impurities. The n-type impurity concentration in the first low-concentration region 24c is equal to or higher than the n-type impurity concentration in the main region 24a. The n-type impurity concentration in the first low-concentration region 24c is higher than the n-type impurity concentration in the main region 24a, for example.

The n-type impurity concentration in the first low-concentration region 24c is, for example, 4×10¹⁴ cm⁻³ or more and 1×10¹⁷ cm⁻³ or less.

The length (d2 in FIG. 3B) of the first high-concentration region 24b in the first direction is equal to, for example, the length (d3 in FIG. 3B) of the first low-concentration region 24c in the first direction.

The sum of the length d2 of the first high-concentration region 24b in the first direction and the length d3 of the first low-concentration region 24c in the first direction is, for example, 0.5 times or more and 2 times or less the length (d1 in FIG. 3A) of the first body region 26a in the second direction. In other words, the repetition pitch (dx in FIG. 3B) between the first high-concentration region 24b and the first low-concentration region 24c is, for example, 0.5 times or more and 2 times or less the length d1 of the first body region 26a in the second direction.

The length (d4 in FIG. 3B) of the first high-concentration region 24b in the second direction is, for example, 0.8 times or more and 1.2 times or less the length (d1 in FIG. 3A) of the first body region 26a in the second direction.

The length (d5 in FIG. 3B) of the first low-concentration region 24c in the second direction is, for example, 0.8 times or more and 1.2 times or less the length (d1 in FIG. 3A) of the first body region 26a in the second direction.

The thickness of the first high-concentration region 24b between the first body region 26a and the main region 24a in the direction from the first face P1 toward the second face P2 is, for example, 0.1 μm or more and 1 μm or less. The thickness of the first low-concentration region 24c between the first body region 26a and the main region 24a in the direction from the first face P1 toward the second face P2 is, for example, 0.1 μm or more and 1 μm or less.

The plurality of second high-concentration regions 24d are provided between the main region 24a and the second body region 26b. The plurality of second high-concentration regions 24d are in contact with the second body region 26b. The plurality of second high-concentration regions 24d are in contact with, for example, the main region 24a.

The plurality of second low-concentration regions 24e are provided between the main region 24a and the second body region 26b. The plurality of second low-concentration regions 24e are in contact with the second body region 26b. The plurality of second low-concentration regions 24e are in contact with, for example, the main region 24a.

As illustrated in FIG. 3A, the second body region 26b extends in the first direction. As illustrated in FIG. 3B, the second high-concentration regions 24d and the second low-concentration regions 24e are alternately provided in the first direction. One second low-concentration region 24e is sandwiched between two second high-concentration regions 24d in the first direction. The second high-concentration region 24d and the second low-concentration region 24e are in contact with each other.

As illustrated in FIG. 3B, the first high-concentration region 24b is provided in the second direction of the second high-concentration region 24d. The first low-concentration region 24c is provided in the second direction of the second low-concentration region 24e.

The second high-concentration region 24d contains, for example, nitrogen (N) as n-type impurities. The n-type impurity concentration in the second high-concentration region 24d is higher than the n-type impurity concentration in the main region 24a. The n-type impurity concentration in the second high-concentration region 24d is higher than the n-type impurity concentration in the second low-concentration region 24e. The n-type impurity concentration in the second high-concentration region 24d is equal to the n-type impurity concentration in the first high-concentration region 24b, for example.

The n-type impurity concentration in the second high-concentration region 24d is, for example, 5×10¹⁶ cm⁻³ or more and 1×10¹⁸ cm⁻³ or less.

The second low-concentration region 24e contains, for example, nitrogen (N) as n-type impurities. The n-type impurity concentration in the second low-concentration region 24e is equal to or higher than the n-type impurity concentration in the main region 24a. The n-type impurity concentration in the second low-concentration region 24e is higher than the n-type impurity concentration in the main region 24a, for example. The n-type impurity concentration in the second low-concentration region 24e is equal to the n-type impurity concentration in the first low-concentration region 24c, for example.

The n-type impurity concentration in the second low-concentration region 24e is, for example, 4×10¹⁴ cm⁻³ or more and 1×10¹⁷ cm⁻³ or less.

The length of the second high-concentration region 24d in the first direction is equal to the length of the second low-concentration region 24e in the first direction, for example.

The sum of the length of the second high-concentration region 24d in the first direction and the length of the second low-concentration region 24e in the first direction is, for example, 0.5 times or more and 2 times or less the length of the second body region 26b in the second direction. In other words, the repetition pitch of the second high-concentration region 24d and the second low-concentration region 24e is, for example, 0.5 times or more and 2 times or less the length d1 of the second body region 26b in the second direction.

The length of the second high-concentration region 24d in the second direction is, for example, 0.8 times or more and 1.2 times or less the length of the second body region 26b in the second direction.

The length of the second low-concentration region 24e in the second direction is, for example, 0.8 times or more and 1.2 times or less the length of the second body region 26b in the second direction.

The thickness of the second high-concentration region 24d between the second body region 26b and the main region 24a in the direction from the first face P1 toward the second face P2 ranges, for example, from 0.1 μm or more and 1 μm or less. The thickness of the second low-concentration region 24e between the second body region 26b and the main region 24a in the direction from the first face P1 toward the second face P2 is, for example, 0.1 μm or more and 1 μm or less.

Next, the functions and effects of the MOSFET 100 of the first embodiment will be described.

For improving the performance of the MOSFET using silicon carbide, it is desirable to reduce the product (Ron×Qoss) of on-resistance and an output charge amount, which is one of performance indexes. The output charge amount (Qoss) is the amount of charge required for charging a capacitance between the drain and the source of the MOSFET.

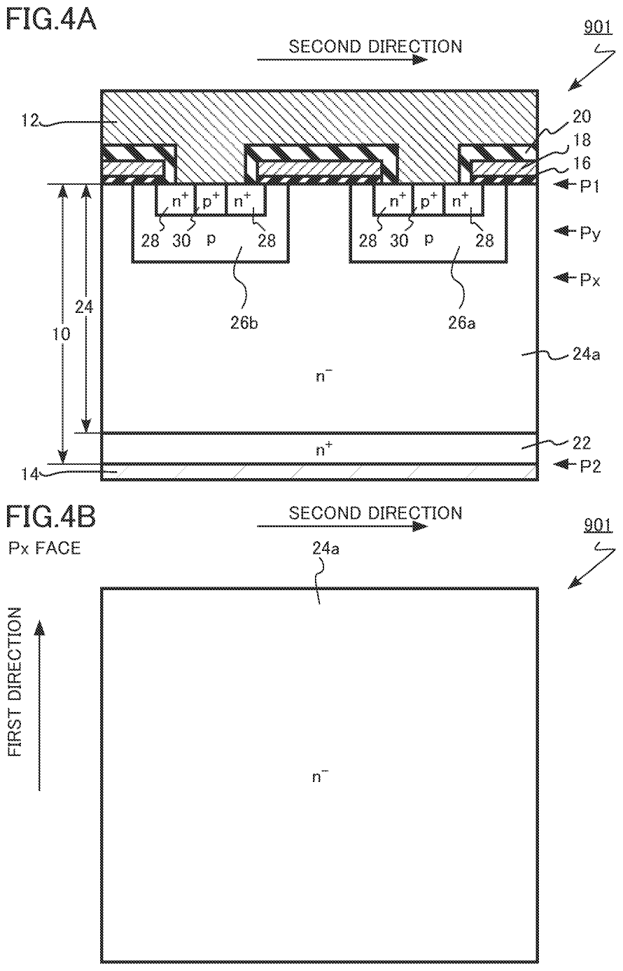

FIGS. 4A and 4B are schematic sectional views of a semiconductor device according to a first comparative example. FIG. 4B is a sectional view taken along face Px of FIG. 4A. FIG. 4A is a diagram corresponding to FIG. 1A of the first embodiment. FIG. 4B is a diagram corresponding to FIG. 3B of the first embodiment.

The semiconductor device according to the first comparative example is a planar-gate-type vertical MOSFET 901 using silicon carbide. The MOSFET 901 of the first comparative example is a DIMOSFET.

The MOSFET 901 of the first comparative example is different from the MOSFET 100 of the first embodiment in that the drift region 24 does not include the first high-concentration region 24b, the first low-concentration region 24c, the second high-concentration region 24d, or the second low-concentration region 24e.

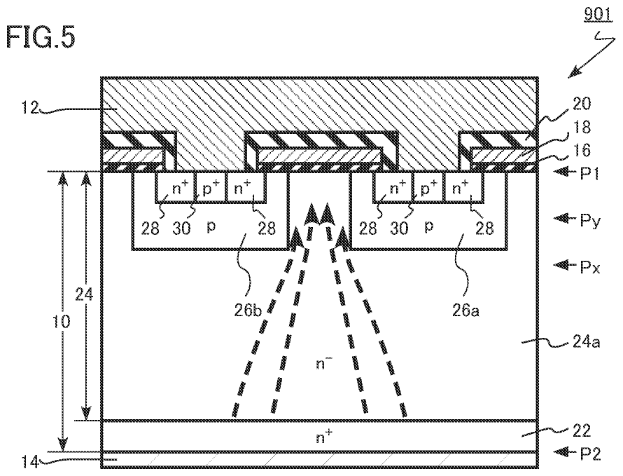

FIG. 5 is an explanatory diagram of functions and effects of the semiconductor device according to the first embodiment. FIG. 5 is a schematic sectional view of the MOSFET 901 of the first comparative example. FIG. 5 is a cross-section corresponding to the cross-section of FIG. 4A.

FIG. 5 is a diagram illustrating a path of an on-current flowing through the MOSFET 901 of the first comparative example. In the MOSFET 901 of the first comparative example, the on-current is concentrated immediately below the gate electrode 18, and the on-current is less likely to spread immediately below the first body region 26a and the second body region 26b. Therefore, it is difficult to reduce the on-resistance of the MOSFET 901.

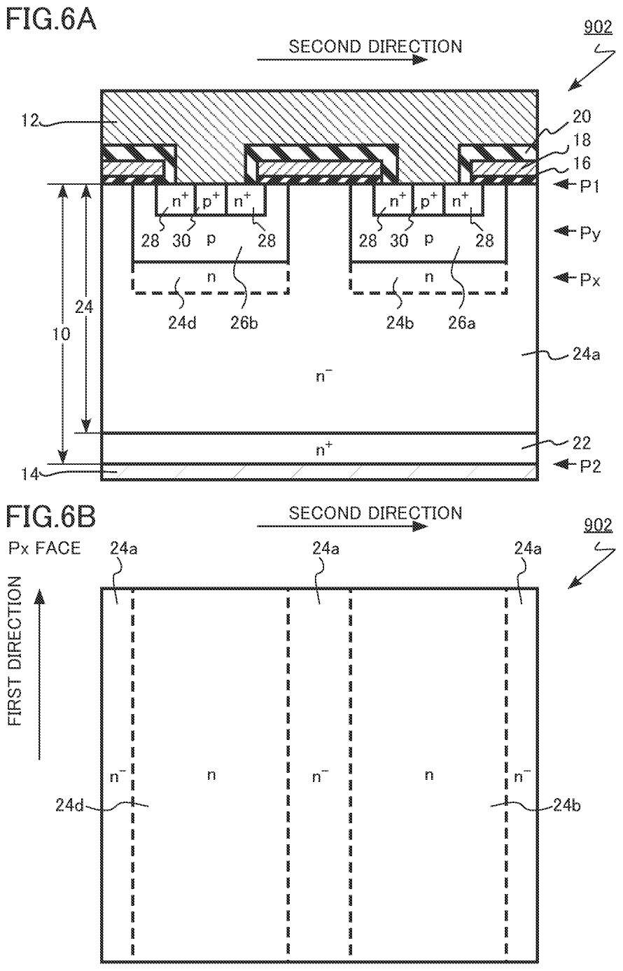

FIGS. 6A and 6B are schematic sectional views of a semiconductor device according to a second comparative example. FIG. 6B is a sectional view taken along face Px of FIG. 6A. FIG. 6A is a diagram corresponding to FIG. 1A of the first embodiment. FIG. 6B is a diagram corresponding to FIG. 3B of the first embodiment.

The semiconductor device according to the second comparative example is a planar-gate-type vertical MOSFET 902 using silicon carbide. The MOSFET 902 of the second comparative example is a DIMOSFET.

The MOSFET 902 of the second comparative example is different from the MOSFET 100 of the first embodiment in that the drift region 24 does not include the first low-concentration region 24c or the second low-concentration region 24e, and the first high-concentration region 24b and the second high-concentration region 24d extend in the first direction.

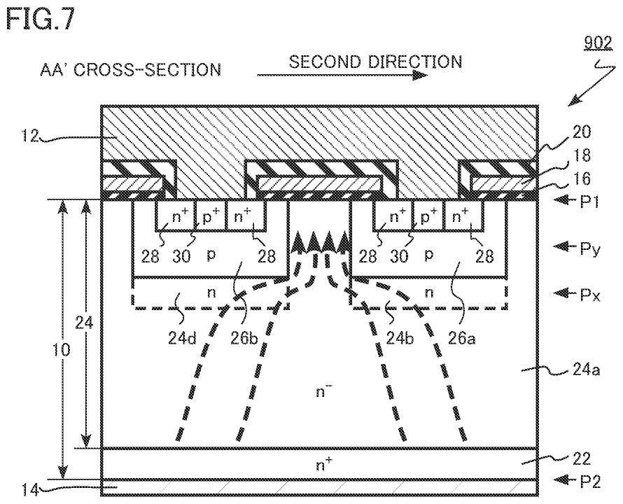

FIG. 7 is an explanatory diagram of functions and effects of the semiconductor device according to the first embodiment. FIG. 7 is a schematic sectional view of a MOSFET 902 of a second comparative example. FIG. 7 is a cross-section corresponding to the cross-section of FIG. 6A.

FIG. 7 is a diagram illustrating a path of an on-current flowing through the MOSFET 902 of the second comparative example. In the MOSFET 902 of the second comparative example, immediately below the first body region 26a and the second body region 26b, the first high-concentration region 24b and the second high-concentration region 24d with high n-type impurity concentration and low electrical resistance are provided. Thus, for example, compared to the MOSFET 901 of the first comparative example, the on-current is more likely to spread immediately below the first body region 26a and the second body region 26b. Therefore, for example, compared to the MOSFET 901 of the first comparative example, the on-resistance (Ron) of the MOSFET 902 can be reduced.

In the MOSFET 902 of the second comparative example, the first high-concentration region 24b and the second high-concentration region 24d with high n-type impurity concentration are provided immediately below the first body region 26a and the second body region 26b. Therefore, when the MOSFET 902 is turned off, a depletion layer from the first body region 26a and the second body region 26b to the drift region 24 is less likely to extend, for example, compared to the MOSFET 901 of the first comparative example.

For this reason, the MOSFET 902 of the second comparative example increases the output charge amount (Qoss), which is the amount of charge required for charging the capacitance between the drain and the source, for example, compared to the MOSFET 901 of the first comparative example. Hence the MOSFET 902 of the second comparative example reduces the on-resistance (Ron) but increases the output charge amount (Qoss) compared to the MOSFET 901 of the first comparative example. Therefore, the MOSFET 902 of the second comparative example does not necessarily reduce the product (Ron×Qoss) of the on-resistance and the output charge amount compared to the MOSFET 901 of the first comparative example.

In the MOSFET 100 of the first embodiment, the first high-concentration regions 24b and the first low-concentration regions 24c are alternately provided immediately below the first body region 26a. By providing the first high-concentration region 24b with higher n-type impurity concentration than the main region 24a, for example, the on-resistance (Ron) of the MOSFET 100 is reduced, for example, compared to the MOSFET 901 of the first comparative example. In addition, by providing the first low-concentration region 24c with lower n-type impurity concentration than the first high-concentration region 24b, for example, compared to the MOSFET 902 of the second comparative example, a depletion layer is more likely to extend from the first body region 26a to the drift region 24 when the MOSFET 100 is turned off, and an output charge amount (Qoss) is reduced.

Furthermore, the product (Ron×Qoss) of the on-resistance and the output charge amount of the MOSFET 100 is reduced, for example, compared to the MOSFET 901 of the first comparative example and the MOSFET 902 of the second comparative example. The reasons for the reduction in the product (Ron×Qoss) of the on-resistance and the output charge amount of the MOSFET 100 is considered as follows.

One reason is considered to be that even when the MOSFET is divided and provided as in the MOSFET 100 of the first embodiment, the on-current spreading promoting effect in the n-type first high-concentration region 24b with relatively low electric resistance immediately below the first body region 26a is not significantly reduced compared to the case where the MOSFET is not divided as in the MOSFET 902 of the second comparative example. Another reason is considered to be that since the first low-concentration region 24c with low n-type impurity concentration, which is divided and provided immediately below the first body region 26a, has an effect of promoting the extension of the depletion layer, the output charge amount (Qoss) does not increase greatly compared to the case where the first high-concentration region 24b is not provided as in the MOSFET 901 of the first comparative example.

The second high-concentration region 24d and the second low-concentration region 24e provided immediately below the second body region 26b also reduce the product (Ron×Qoss) of the on-resistance and the output charge amount of the MOSFET 100 by the same function as the first high-concentration region 24b and the first low-concentration region 24c.

As described above, according to the MOSFET 100 of the first embodiment, the product (Ron×Qoss) of the on-resistance and the output charge amount is reduced.

The sum (dx) of the length d2 of the first high-concentration region 24b in the first direction and the length d3 of the first low-concentration region 24c in the first direction is preferably 0.5 times or more and 2 times or less the length (d1 in FIG. 3A) of the first body region 26a in the second direction. Satisfying the above range leads to a further reduction in the product (Ron×Qoss) of the on-resistance and the output charge amount of the MOSFET 100.

The length (d4 in FIG. 3B) of the first high-concentration region 24b in the second direction is preferably 0.8 times or more and 1.2 times or less the length (d1 in FIG. 3A) of the first body region 26a in the second direction. Satisfying the above range leads to a further reduction in the product (Ron×Qoss) of the on-resistance and the output charge amount of the MOSFET 100.

### First Modification

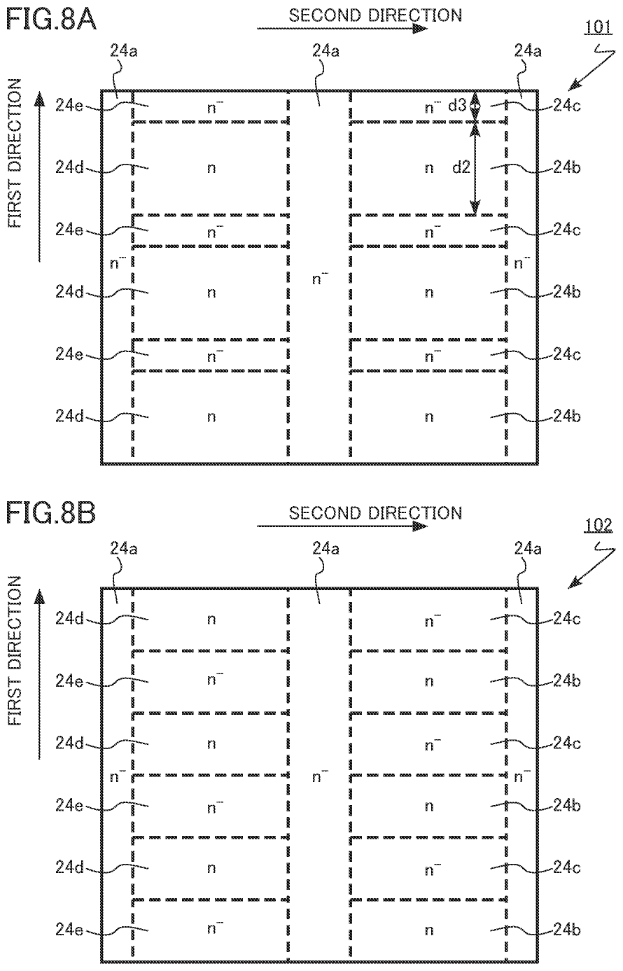

FIG. 8A is a schematic view of a semiconductor device according to a first modification of the first embodiment. FIG. 8A is a diagram corresponding to FIG. 3B of the first embodiment.

A semiconductor device according to a first modification of the first embodiment is a MOSFET 101. The MOSFET 101 of the first modification is different from the MOSFET 100 of the first embodiment in that the length (d2 in FIG. 8A) of the first high-concentration region 24b in the first direction is longer than the length (d3 in FIG. 8A) of the first low-concentration region 24c in the first direction.

According to the MOSFET 101 of the first modification, similarly to the MOSFET 100 of the first embodiment, the product (Ron×Qoss) of the on-resistance and the output charge amount is reduced. In addition, the on-resistance is further reduced due to the length (d2 in FIG. 8A) of the first high-concentration region 24b in the first direction being longer than the length (d3 in FIG. 8A) of the first low-concentration region 24c in the first direction.

### Second Modification

FIG. 8B is a schematic view of a semiconductor device according to a second modification of the first embodiment. FIG. 8B is a diagram corresponding to FIG. 3B of the first embodiment.

A semiconductor device according to a second modification of the first embodiment is a MOSFET 102. The MOSFET 102 of the second modification is different from the MOSFET 100 of the first embodiment in that the first high-concentration region 24b is provided in the second direction of the second low-concentration region 24e, and the first low-concentration region 24c is provided in the second direction of the second high-concentration region 24d.

According to the MOSFET 102 of the second modification, similarly to the MOSFET 100 of the first embodiment, the product (Ron×Qoss) of the on-resistance and the output charge amount is reduced. In addition, due to the first high-concentration region 24b being provided in the second direction of the second low-concentration region 24e and the first low-concentration region 24c being provided in the second direction of the second high-concentration region 24d, for example, the region where the on-current flows is homogenized in the chip. Therefore, for example, the operation characteristics of the MOSFET 102 are stabilized.

As described above, according to the first embodiment and the modified example, it is possible to achieve a semiconductor device capable of reducing the product (Ron×Qoss) of the on-resistance and the output charge amount.

### Second Embodiment

A semiconductor device according to a second embodiment is different from the semiconductor device according to the first embodiment in that the first silicon carbide region has a first portion in contact with the first face and the second silicon carbide region, and the first electrode is in contact with the first portion. Hereinafter, a part of the description of contents overlapping with those of the first embodiment will be omitted.

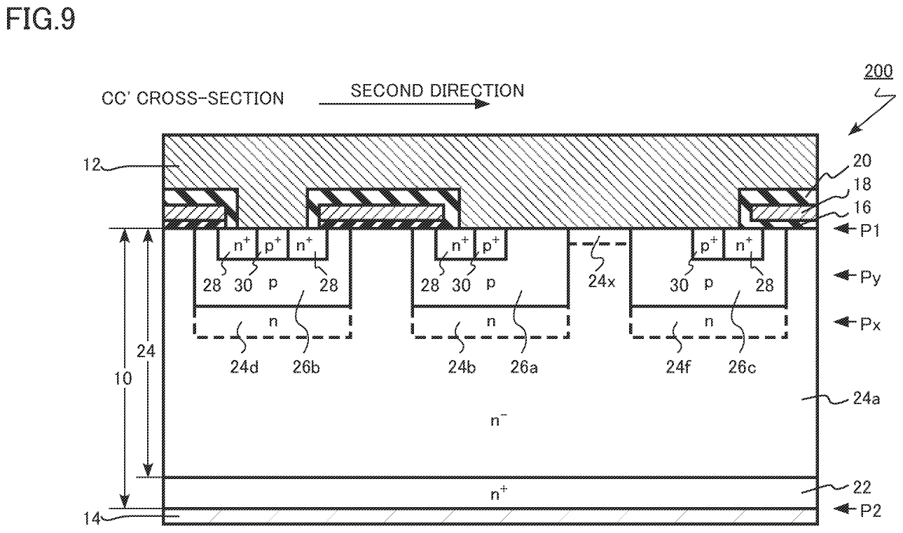

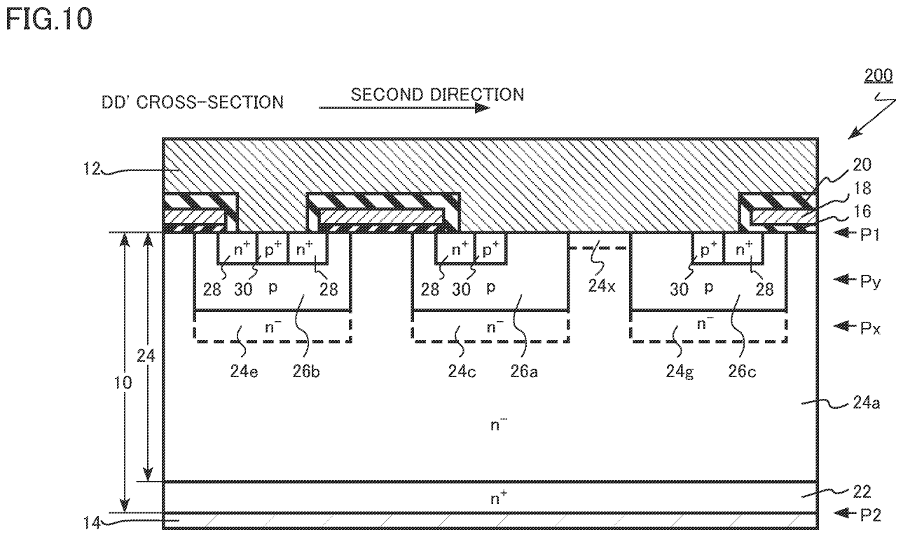

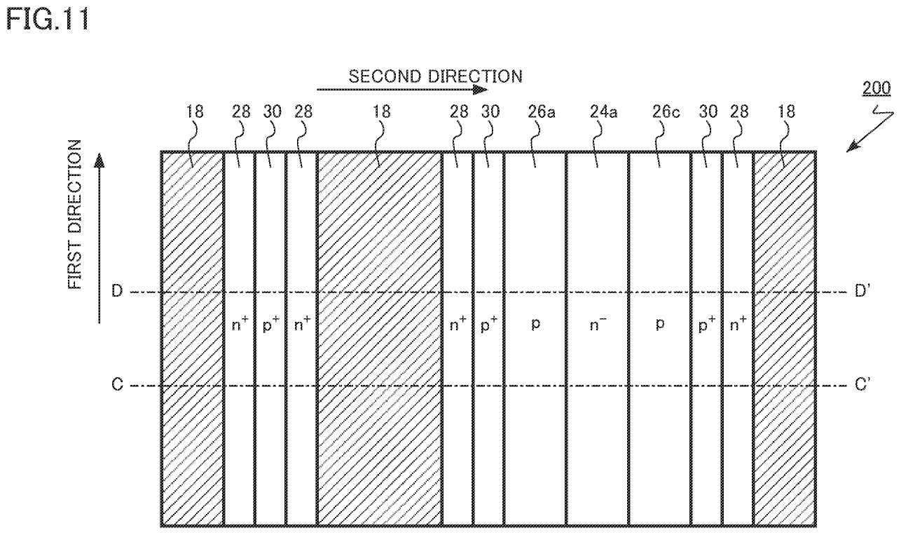

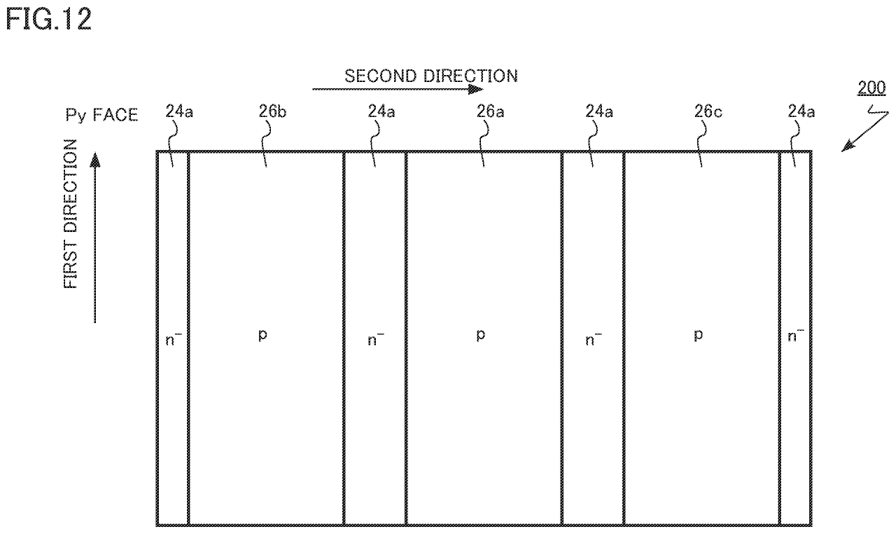

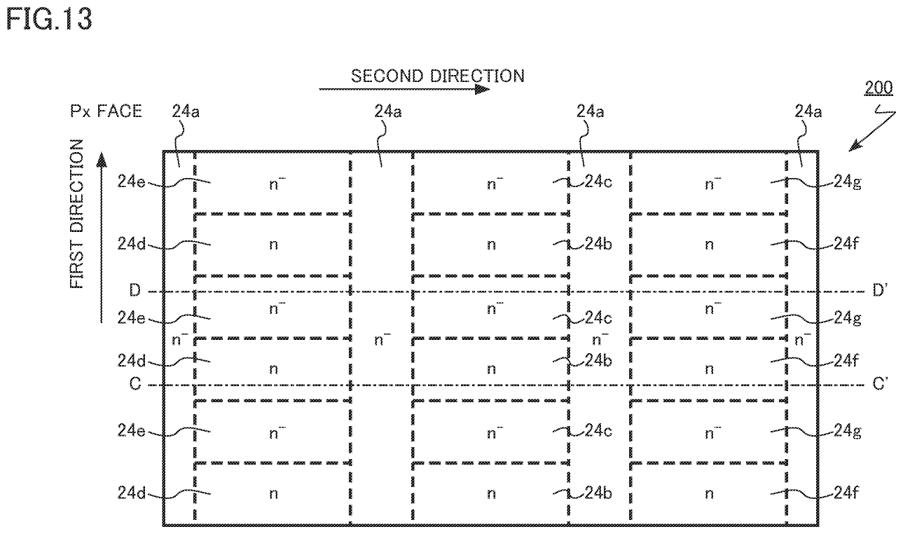

FIGS. 9 and 10 are schematic sectional views of the semiconductor device according to the second embodiment. FIG. 11 is a schematic top view of the second embodiment. FIG. 11 is a view of the pattern of the gate electrode overlaid with the pattern of the silicon carbide region on the front surface of the silicon carbide layer. FIGS. 12 and 13 are schematic sectional views of the semiconductor device according to the second embodiment.

FIG. 9 is a cross-section taken along line CC′ of FIGS. 11 and 13. FIG. 10 is a cross-section taken along line DD′ of FIGS. 11 and 13. FIG. 12 is a sectional view taken along face Py of FIGS. 9 and 10. FIG. 13 is a sectional view taken along face Px of FIGS. 9 and 10.

The semiconductor device according to the second embodiment is a planar-gate-type vertical MOSFET 200 using silicon carbide. The MOSFET 200 of the second embodiment is, for example, a DIMOSFET in which a body region and a source region are formed by ion implantation. In addition, the semiconductor device according to the second embodiment includes a Schottky barrier diode (SBD) as a built-in diode. The MOSFET 200 of the second embodiment is different from the MOSFET 100 of the first embodiment in including an SBD as a built-in diode

A case where the first conductivity type is n-type and the second conductivity type is p-type will be described below as an example. The MOSFET 200 is a vertical n-channel MOSFET using electrons as carriers.

The MOSFET 200 includes a silicon carbide layer 10, a source electrode 12, a drain electrode 14, a gate insulating layer 16, a gate electrode 18, and an interlayer insulating layer 20. The source electrode 12 is an example of a first electrode. The drain electrode 14 is an example of a second electrode.

In the silicon carbide layer 10, an n⁺ type drain region 22, an n⁻ type drift region 24, a p-type first body region 26a, a p-type second body region 26b, a p-type third body region 26c, an n⁺ type source region 28, and a p⁺ type body contact region 30 are provided. The drift region 24 is an example of a first silicon carbide region. The first body region 26a is an example of a second silicon carbide region. The second body region 26b is an example of a fourth silicon carbide region. The source region 28 is an example of a third silicon carbide region.

The drift region 24 includes a main region 24a, a first high-concentration region 24b, a first low-concentration region 24c, a second high-concentration region 24d, a second low-concentration region 24e, a third high-concentration region 24f, and a third low-concentration region 24g. The main region 24a is an example of a first region. The first high-concentration region 24b is an example of a second region. The first low-concentration region 24c is an example of a third region. The second high-concentration region 24d is an example of a fourth region. The second low-concentration region 24e is an example of a fifth region.

The p-type first body region 26a, second body region 26b, and third body region 26c are provided between the drift region 24 and the first face P1. The first body region 26a, the second body region 26b, and the third body region 26c are separated from each other.

The first body region 26a, the second body region 26b, and the third body region 26c extend in the first direction parallel to the first face P1. The second body region 26b and the third body region 26c are provided in the second direction parallel to the first face P1 and orthogonal to the first direction with respect to the first body region 26a. The first body region 26a is provided between the second body region 26b and the third body region 26c.

The first body region 26a, the second body region 26b, and the third body region 26c function as the channel regions of the MOSFET 200.

The first body region 26a, the second body region 26b, and the third body region 26c contain, for example, aluminum (Al) as p-type impurities. The p-type impurity concentration in the first body region 26a, the second body region 26b, and the third body region 26c is, for example, 1×10¹⁷ cm⁻³ or more and 1×10¹⁸ cm⁻³ or less.

The depths of the first body region 26a, the second body region 26b, and the third body region 26c are, for example, 0.3 μm or more and 0.8 μm or less.

The first body region 26a, the second body region 26b, and the third body region 26c are fixed to the electric potential of the source electrode 12.

The n-type drift region 24 is provided between the drain region 22 and the first face P1. The n-type drift region 24 includes a first portion 24x. The first portion 24x is, for example, a part of the main region 24a.

The first portion 24x is in contact with the first face P1. The first portion 24x is provided between the first body region 26a and the third body region 26c. The first portion 24x is in contact with the first body region 26a and the third body region 26c.

The source electrode 12 is in contact with the source region 28. The source electrode 12 is in contact with the body contact region 30.

The source electrode 12 is in contact with the first portion 24x of the drift region 24. The source electrode 12 is in contact with the first body region 26a adjacent to the first portion 24x. The source electrode 12 is in contact with the third body region 26c adjacent to the first portion 24x.

The source electrode 12 contains metal. The metal forming the source electrode 12 is, for example, a stacked structure of titanium (Ti) and aluminum (Al). A portion of the source electrode 12 in contact with the source region 28 is, for example, metal silicide. The metal silicide is, for example, titanium silicide or nickel silicide. For example, metal silicide is not provided in a portion of the source electrode 12 in contact with the first portion 24x.

The junction between the first portion 24x and the source electrode 12 is a Schottky junction.

The source electrode 12, the first portion 24x, the main region 24a, the drain region 22, and the drain electrode 14 constitute an SBD. The source electrode 12 functions as an anode electrode of the SBD, and the drain electrode 14 functions as a cathode electrode of the SBD.

The drift region 24 includes an n-type main region 24a, a plurality of n-type first high-concentration regions 24b, a plurality of n-type first low-concentration regions 24c, a plurality of n-type second high-concentration regions 24d, a plurality of n-type second low-concentration regions 24e, a plurality of n-type third high-concentration regions 24f, and a plurality of n-type third low-concentration regions 24g.

The main region 24a contains, for example, nitrogen (N) as n-type impurities. The n-type impurity concentration in the main region 24a is, for example, 4×10¹⁴ cm⁻³ or more and 1×10¹⁷ cm⁻³ or less.

The plurality of third high-concentration regions 24f are provided between the main region 24a and the third body region 26c. The plurality of third high-concentration regions 24f are in contact with the third body region 26c. The plurality of third high-concentration regions 24f are in contact with, for example, the main region 24a.

The plurality of third low-concentration regions 24g are provided between the main region 24a and the third body region 26c. The plurality of third low-concentration regions 24g are in contact with the third body region 26c. The third low-concentration region 24g is in contact with the main region 24a, for example.

As illustrated in FIG. 12, the third body region 26c extends in the first direction. As illustrated in FIG. 13, the third high-concentration regions 24f and the third low-concentration regions 24g are alternately provided in the first direction. One third low-concentration region 24g is sandwiched between two third high-concentration regions 24f in the first direction. The third high-concentration region 24f and the third low-concentration region 24g are in contact with each other.

The third high-concentration region 24f is provided in the second direction of the first high-concentration region 24b. The third low-concentration region 24g is provided in the second direction of the first low-concentration region 24c.

The third high-concentration region 24f contains, for example, nitrogen (N) as n-type impurities. The n-type impurity concentration in the third high-concentration region 24f is higher than the n-type impurity concentration in the main region 24a. The n-type impurity concentration in the third high-concentration region 24f is higher than the n-type impurity concentration in the third low-concentration region 24g. The n-type impurity concentration in the third high-concentration region 24f is equal to the n-type impurity concentration in the first high-concentration region 24b, for example.

The n-type impurity concentration in the third high-concentration region 24f is, for example, 5×10¹⁶ cm⁻³ or more and 1×10¹⁸ cm⁻³ or less.

The third low-concentration region 24g contains, for example, nitrogen (N) as n-type impurities. The n-type impurity concentration in the third low-concentration region 24g is equal to or higher than the n-type impurity concentration in the main region 24a. The n-type impurity concentration in the third low-concentration region 24g is higher than the n-type impurity concentration in the main region 24a, for example. The n-type impurity concentration in the third low-concentration region 24g is equal to the n-type impurity concentration in the first low-concentration region 24c, for example.

The n-type impurity concentration in the third low-concentration region 24g is, for example, 4×10¹⁴ cm⁻³ or more and 1×10¹⁷ cm⁻³ or less.

Next, functions and effects of the MOSFET 200 of the second embodiment will be described.

In the MOSFET 200 according to the second embodiment, similarly to the MOSFET 100 according to the first embodiment, the drift region 24 includes the first high-concentration region 24b, the first low-concentration region 24c, the second high-concentration region 24d, and the second low-concentration region 24e, so that the product (Ron×Qoss) of the on-resistance and the output charge amount is reduced.

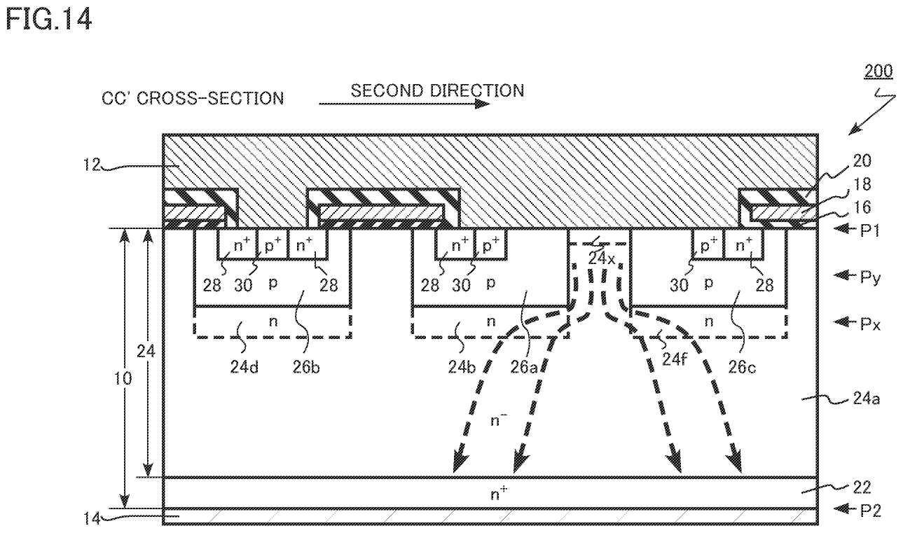

FIG. 14 is an explanatory diagram of functions and effects of the semiconductor device according to the second embodiment. FIG. 14 is a schematic sectional view of the MOSFET 200 of the second embodiment. FIG. 14 is a cross-section corresponding to FIG. 9.

FIG. 14 is a diagram illustrating a path of an on-current flowing through the SBD of the MOSFET 200 of the second embodiment. In the MOSFET 200 according to the second embodiment, immediately below the first body region 26a and the third body region 26c, the first high-concentration region 24b and the third high-concentration region 24f with high n-type impurity concentration and low electrical resistance are provided. Hence the on-current of the SBD is more likely to spread immediately below the first body region 26a and the third body region 26c. This enables an increase in the on-current of the SBD built in the MOSFET 200.

As described above, according to the second embodiment, similarly to the first embodiment, it is possible to achieve a semiconductor device capable of reducing the product (Ron×Qoss) of the on-resistance and the output charge amount. In addition, it is possible to increase the on-current of the built-in SBD.

### Third Embodiment

A semiconductor device according to a third embodiment is different from the semiconductor device according to the first embodiment in that the pattern of the gate electrode has a lattice shape. Hereinafter, a part of the description of contents overlapping with those of the first embodiment will be omitted.

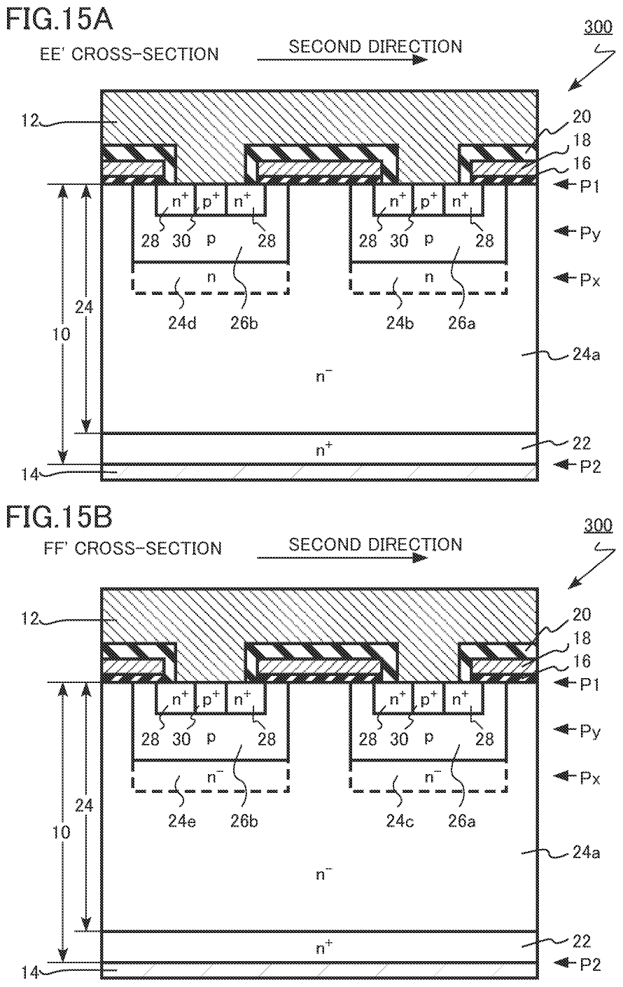

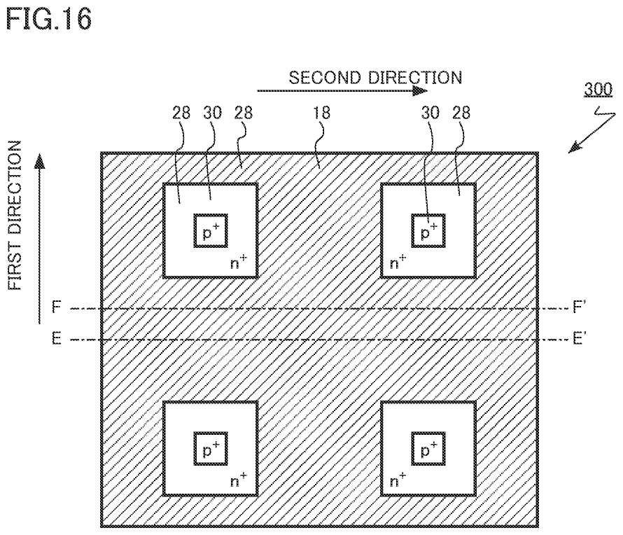

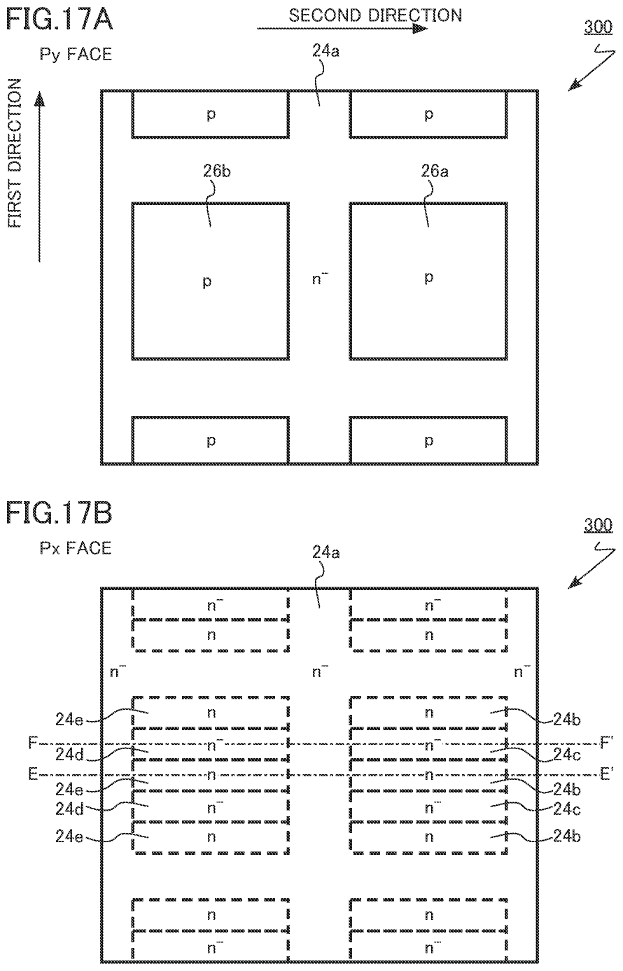

FIGS. 15A and 15B are schematic sectional views of the semiconductor device according to the third embodiment. FIG. 16 is a schematic top view of the third embodiment. FIG. 16 is a view of the pattern of the gate electrode overlaid with the pattern of the silicon carbide region on the front surface of the silicon carbide layer. FIGS. 17A and 17B are schematic sectional views of the semiconductor device according to the third embodiment.

FIG. 15A is a cross-section taken along line EE′ of FIGS. 16 and 17B. FIG. 15B is a cross-section taken along line FF′ of FIGS. 16 and 17B. FIG. 17A is a sectional view taken along face Py of FIGS. 15A and 15B. FIG. 17B is a sectional view taken along face Px of FIGS. 15A and 15B.

The semiconductor device according to the third embodiment is a planar-gate-type vertical MOSFET 300 using silicon carbide. The MOSFET 300 of the third embodiment is, for example, a DIMOSFET in which a body region and a source region are formed by ion implantation.

A case where the first conductivity type is n-type and the second conductivity type is p-type will be described below as an example. The MOSFET 300 is a vertical n-channel MOSFET using electrons as carriers.

The MOSFET 300 includes a silicon carbide layer 10, a source electrode 12, a drain electrode 14, a gate insulating layer 16, a gate electrode 18, and an interlayer insulating layer 20. The source electrode 12 is an example of a first electrode. The drain electrode 14 is an example of a second electrode.

In the silicon carbide layer 10, an n⁺ type drain region 22, an n⁻ type drift region 24, a p-type first body region 26a, a p-type second body region 26b, an n⁺ type source region 28, and a p⁺ type body contact region 30 are provided. The drift region 24 is an example of a first silicon carbide region. The first body region 26a is an example of a second silicon carbide region. The second body region 26b is an example of a fourth silicon carbide region. The source region 28 is an example of a third silicon carbide region.

The drift region 24 includes a main region 24a, a first high-concentration region 24b, a first low-concentration region 24c, a second high-concentration region 24d, and a second low-concentration region 24e. The main region 24a is an example of a first region. The first high-concentration region 24b is an example of a second region. The first low-concentration region 24c is an example of a third region. The second high-concentration region 24d is an example of a fourth region. The second low-concentration region 24e is an example of a fifth region.

As illustrated in FIG. 16, the gate electrode 18 has a lattice-shaped pattern. As illustrated in FIG. 17A, the p-type first body region 26a and the p-type second body region 26b each have a square pattern.

As illustrated in FIG. 17B, the first high-concentration regions 24b and the first low-concentration regions 24c are alternately provided in the first direction immediately below first body region 26a. The second high-concentration regions 24d and the second low-concentration regions 24e are alternately provided in the first direction immediately below the second body region 26b.

In the MOSFET 300 of the third embodiment, similarly to the MOSFET 100 of the first embodiment, the drift region 24 includes the first high-concentration region 24b, the first low-concentration region 24c, the second high-concentration region 24d, and the second low-concentration region 24e, so that the product (Ron×Qoss) of the on-resistance and the output charge amount is reduced.

As described above, according to the third embodiment, similarly to the first embodiment, it is possible to achieve a semiconductor device capable of reducing the product (Ron×Qoss) of the on-resistance and the output charge amount.

### Fourth Embodiment

A semiconductor device according to a fourth embodiment includes: a silicon carbide layer having a first face and a second face facing the first face; a first electrode provided on a side of the first face of the silicon carbide layer; a second electrode provided on a side of the second face of the silicon carbide layer; a first silicon carbide region of a first conductivity type provided in the silicon carbide layer; a second silicon carbide region of a second conductivity type provided in the silicon carbide layer and provided between the first silicon carbide region and the first face; a third silicon carbide region of the first conductivity type provided in the silicon carbide layer and provided between the second silicon carbide region and the first face, the third silicon carbide region being in contact with the first electrode; a trench provided in the silicon carbide layer, the trench being in contact with the first silicon carbide region, the second silicon carbide region, and the third silicon carbide region; a gate electrode provided in the trench and facing the second silicon carbide region; and a gate insulating layer provided between the gate electrode and the second silicon carbide region. The first silicon carbide region includes a first region, a plurality of second regions provided between the first region and the second silicon carbide region and in contact with the second silicon carbide region, and a plurality of third regions provided between the first region and the second silicon carbide region and in contact with the second silicon carbide region. The second regions and the third regions are alternately provided in a first direction parallel to the first face. A first conductivity type impurity concentration in each of the second regions is higher than a first conductivity type impurity concentration in the first region and a first conductivity type impurity concentration in each of the third regions. A semiconductor device according to a fourth embodiment is different from the semiconductor device according to the first embodiment in that the semiconductor device has a trench gate structure. Hereinafter, a part of the description of contents overlapping with those of the first embodiment will be omitted.

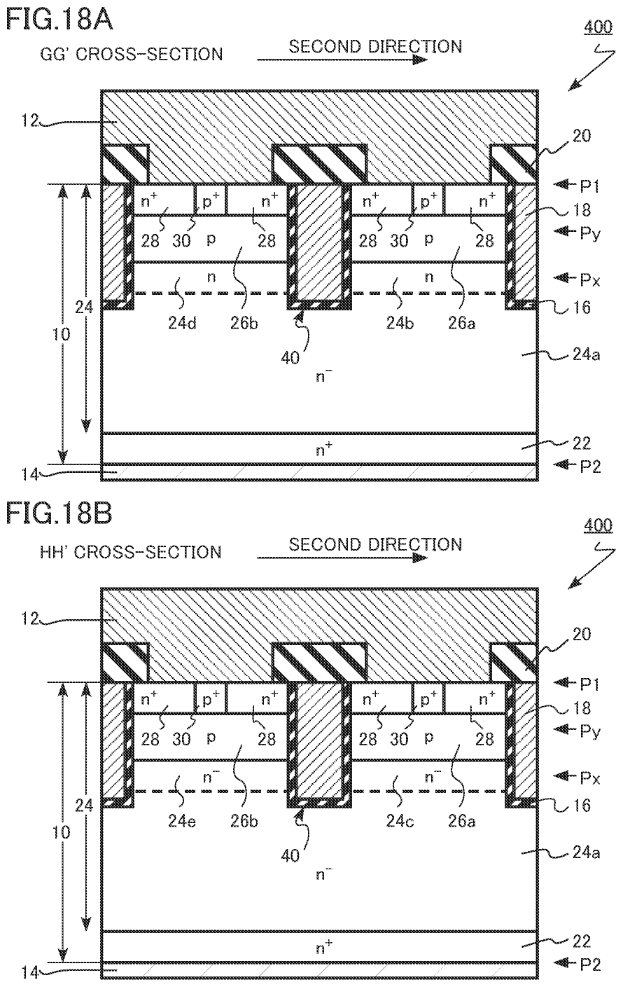

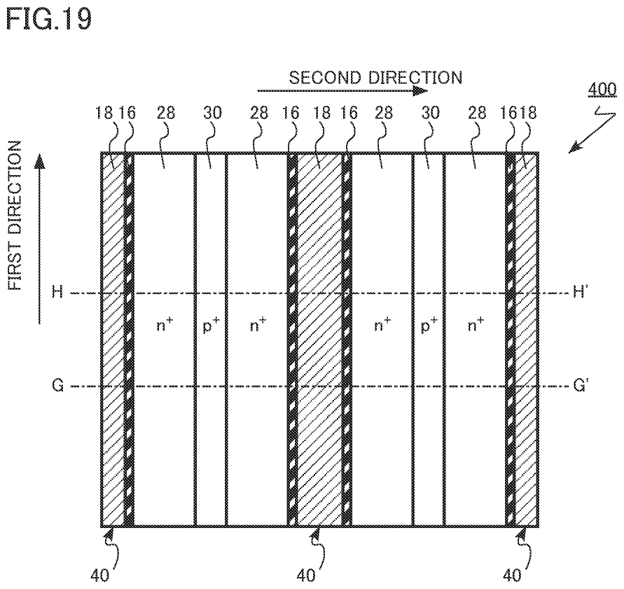

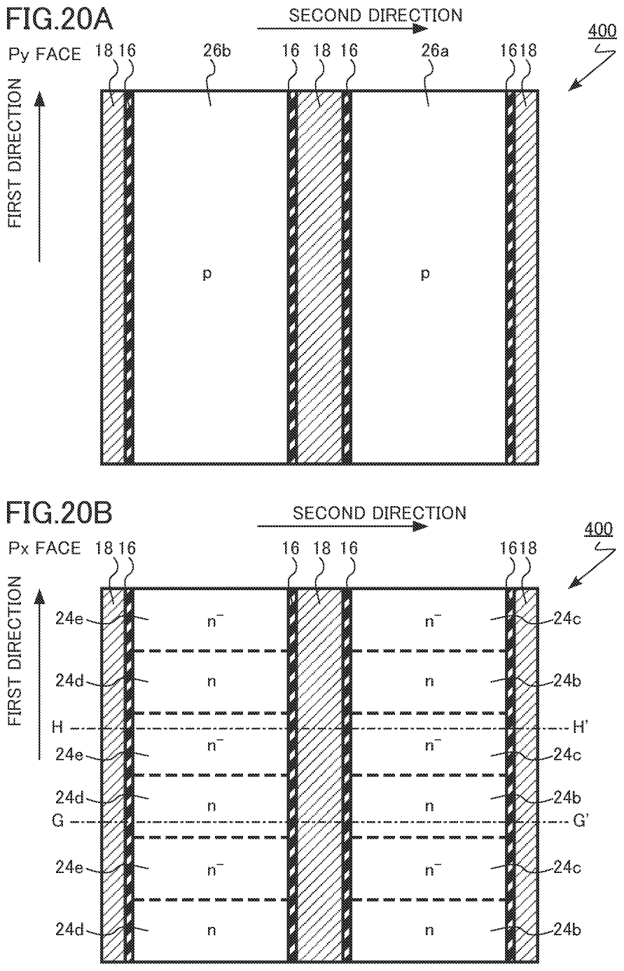

FIGS. 18A and 18B are schematic sectional views of the semiconductor device according to the fourth embodiment. FIG. 19 is a schematic top view of the fourth embodiment. FIG. 19 is a view of the patterns of the trench and the gate electrode overlaid with the pattern of the silicon carbide region on the front surface of the silicon carbide layer. FIGS. 20A and 20B are schematic sectional views of the semiconductor device according to the fourth embodiment.

FIG. 18A is a cross-section taken along line GG′ of FIGS. 19 and 20B. FIG. 18B is a cross-section taken along line HH′ of FIGS. 19 and 20B. FIG. 20A is a sectional view taken along face Py of FIGS. 18A and 18B. FIG. 20B is a sectional view taken along face Px of FIGS. 18A and 18B.

The semiconductor device according to the fourth embodiment is a trench-gate-type vertical MOSFET 400 using silicon carbide. In the MOSFET 400 of the fourth embodiment, a gate electrode is formed in a trench provided in a silicon carbide layer.

A case where the first conductivity type is n-type and the second conductivity type is p-type will be described below as an example. The MOSFET 400 is a vertical n-channel MOSFET using electrons as carriers.

The MOSFET 400 includes a silicon carbide layer 10, a source electrode 12, a drain electrode 14, a gate insulating layer 16, a gate electrode 18, and an interlayer insulating layer 20. The source electrode 12 is an example of a first electrode. The drain electrode 14 is an example of a second electrode.

In the silicon carbide layer 10, an n⁺ type drain region 22, an n⁻ type drift region 24, a p-type first body region 26a, a p-type second body region 26b, an n⁺ type source region 28, a p⁺ type body contact region 30, and a trench 40 are provided. The drift region 24 is an example of a first silicon carbide region. The first body region 26a is an example of a second silicon carbide region. The second body region 26b is an example of a fourth silicon carbide region. The source region 28 is an example of a third silicon carbide region.

The drift region 24 includes a main region 24a, a first high-concentration region 24b, a first low-concentration region 24c, a second high-concentration region 24d, and a second low-concentration region 24e. The main region 24a is an example of a first region. The first high-concentration region 24b is an example of a second region. The first low-concentration region 24c is an example of a third region. The second high-concentration region 24d is an example of a fourth region. The second low-concentration region 24e is an example of a fifth region.

The trench 40 is provided in the silicon carbide layer 10. The trench 40 is a part of the silicon carbide layer 10. The trench 40 is a recess formed in the silicon carbide layer 10.

The trench 40 is in contact with the drift region 24, the first body region 26a, the second body region 26b, and the source region 28. The trench 40 penetrates the drift region 24, the first body region 26a, and the second body region 26b.

The gate electrode 18 is provided in the silicon carbide layer 10. The gate electrode 18 is provided in the silicon carbide layer 10 with the gate insulating layer 16 interposed therebetween. The gate electrode 18 is provided in the trench 40. The gate electrode 18 faces the first body region 26a. The gate electrode 18 faces the second body region 26b.

The gate insulating layer 16 is provided between the gate electrode 18 and the first body region 26a. The gate insulating layer 16 is provided between the gate electrode 18 and the second body region 26b.

As illustrated in FIG. 19, the trench 40 and the gate electrode 18 extend in the first direction. The trench 40 and the gate electrode 18 each have a stripe pattern. As illustrated in FIG. 20A, the p-type first body region 26a and the p-type second body region 26b extend in the first direction.

As illustrated in FIG. 20B, the first high-concentration regions 24b and the first low-concentration regions 24c are alternately provided in the first direction immediately below first body region 26a. The second high-concentration regions 24d and the second low-concentration regions 24e are alternately provided in the first direction immediately below the second body region 26b.

In the MOSFET 400 according to the fourth embodiment, similarly to the MOSFET 100 according to the first embodiment, the drift region 24 includes the first high-concentration region 24b, the first low-concentration region 24c, the second high-concentration region 24d, and the second low-concentration region 24e, so that the product (Ron×Qoss) of the on-resistance and the output charge amount is reduced.

As described above, according to the fourth embodiment, similarly to the first embodiment, it is possible to achieve a semiconductor device capable of reducing the product (Ron×Qoss) of the on-resistance and the output charge amount.

In the first to fourth embodiments, the case of 4H—SiC has been described as an example of the crystal structure of SiC, but the present disclosure can also be applied to devices using SiC with other crystal structures such as 6H—SiC and 3C—SiC. It is also possible to apply a face other than the (0001) face to the surface of the silicon carbide layer 10.

In the first to fourth embodiments, the case where the first conductivity type is n-type and the second conductivity type is p-type has been described as an example, but the first conductivity type may be p-type and the second conductivity type may be n-type.

In the first to fourth embodiments, aluminum (Al) is exemplified as the p-type impurity, but boron (B) can also be used. Further, nitrogen (N) and phosphorus (P) have been exemplified as the n-type impurities, but arsenic (As), antimony (Sb), and the like can also be applied.

In the second embodiment, the case where the semiconductor device is a planar-gate-type MOSFET with a built-in SBD has been described as an example, but the semiconductor device may be, for example, a trench-gate-type MOSFET with a built-in SBD.

In the first to fourth embodiments, the case where the semiconductor device is a MOSFET has been described as an example, but the semiconductor device may be an insulated-gate bipolar transistor (IGBT).

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a silicon carbide layer having a first face and a second face facing the first face;
a first electrode provided on a side of the first face of the silicon carbide layer;
a second electrode provided on a side of the second face of the silicon carbide layer;
a first silicon carbide region of a first conductivity type provided in the silicon carbide layer;
a second silicon carbide region of a second conductivity type provided in the silicon carbide layer and provided between the first silicon carbide region and the first face;
a third silicon carbide region of the first conductivity type provided in the silicon carbide layer and provided between the second silicon carbide region and the first face, the third silicon carbide region being in contact with the first electrode;
a gate electrode provided on the first face side of the silicon carbide layer and facing the second silicon carbide region; and
a gate insulating layer provided between the gate electrode and the second silicon carbide region, wherein
the first silicon carbide region includes
a first region,
a plurality of second regions provided between the first region and the second silicon carbide region and in contact with the second silicon carbide region, and
a plurality of third regions provided between the first region and the second silicon carbide region and in contact with the second silicon carbide region,
the second regions and the third regions are alternately provided in a first direction parallel to the first face, and
a first conductivity type impurity concentration in each of the second regions is higher than a first conductivity type impurity concentration in the first region and a first conductivity type impurity concentration in each of the third regions.

2. The semiconductor device according to claim 1, wherein the second silicon carbide region extends in the first direction.

3. The semiconductor device according to claim 1, wherein the gate electrode extends in the first direction.

4. The semiconductor device according to claim 1, wherein a length of one of the second regions in the first direction is longer than a length of one of the third regions in the first direction.

5. The semiconductor device according to claim 1, wherein a sum of one of one of the second regions in the first direction and a length of one of the third region in the first direction is 0.5 times or more and 2 times or less a length of the second silicon carbide region in a second direction perpendicular to the first direction and parallel to the first face.

6. The semiconductor device according to claim 1, wherein a first conductivity type impurity concentration in each of the third regions is higher than a first conductivity type impurity concentration in the first region.

7. The semiconductor device according to claim 1, further comprising a fourth silicon carbide region of the second conductivity type provided in the silicon carbide layer and provided between the first silicon carbide region and the first face, the fourth silicon carbide region being separated from the second silicon carbide region, wherein
the gate electrode faces the fourth silicon carbide region, and
the gate insulating layer is provided between the gate electrode and the fourth silicon carbide region,
the first silicon carbide region includes
a plurality of fourth regions provided between the first region and the fourth silicon carbide region and in contact with the fourth silicon carbide region, and
a plurality of fifth regions provided between the first region and the fourth silicon carbide region and in contact with the fourth silicon carbide region,
the fourth regions and the fifth regions are alternately provided in the first direction, and
a first conductivity type impurity concentration in each of the fourth regions is higher than a first conductivity type impurity concentration in the first region and a first conductivity type impurity concentration in each of the fifth regions.

8. The semiconductor device according to claim 1, wherein
the first silicon carbide region has a first portion in contact with the first face and the second silicon carbide region, and
the first electrode is in contact with the first portion.

9. A semiconductor device comprising:
a silicon carbide layer having a first face and a second face facing the first face;
a first electrode provided on a side of the first face of the silicon carbide layer;
a second electrode provided on a side of the second face of the silicon carbide layer;
a first silicon carbide region of a first conductivity type provided in the silicon carbide layer;
a second silicon carbide region of a second conductivity type provided in the silicon carbide layer and provided between the first silicon carbide region and the first face;
a third silicon carbide region of the first conductivity type provided in the silicon carbide layer and provided between the second silicon carbide region and the first face, the third silicon carbide region being in contact with the first electrode;
a gate electrode provided in the silicon carbide layer and facing the second silicon carbide region; and
a gate insulating layer provided between the gate electrode and the second silicon carbide region, wherein
the first silicon carbide region includes
a first region,
a plurality of second regions provided between the first region and the second silicon carbide region and in contact with the second silicon carbide region, and
a plurality of third regions provided between the first region and the second silicon carbide region and in contact with the second silicon carbide region,
the second regions and the third regions are alternately provided in a first direction parallel to the first face, and
a first conductivity type impurity concentration in each of the second regions is higher than a first conductivity type impurity concentration in the first region and a first conductivity type impurity concentration in each of the third regions.

10. The semiconductor device according to claim 9, wherein the second silicon carbide region extends in the first direction.

11. The semiconductor device according to claim 9, wherein the gate electrode extends in the first direction.
